(19) United States
(12) Patent Application Publication
(10) Pub. No.: US 2017/0130331 A1
(43) Pub. Date: May 11, 2017

(54) METHOD FOR MOCVD GAS SHOWERHEAD PRETREATMENT

(71) Applicant: Advanced Micro-Fabrication Equipment Inc, Shanghai, Shanghai (CN)

(72) Inventors: Yingbin LIU, Shanghai (CN); Zhiyou DU, Shanghai (CN)

(21) Appl. No.: 15/210,198

(22) Filed: Jul. 14, 2016

(30) Foreign Application Priority Data
Nov. 6, 2015 (CN) 201510747873.3

(51) Int. Cl. C23C 16/44; C23C 16/46; C23C 16/458; C23C 16/455

(52) U.S. Cl. CPC C23C 16/4412; C23C 16/45565; C23C 16/46; C23C 16/463; C23C 16/458

(57) ABSTRACT

A method for MOCVD gas showerhead pretreatment, which includes: providing a reaction chamber, an evacuating system located at bottom of reaction chamber and a gas showerhead fixed on top of reaction chamber. The gas showerhead includes the cooling plate at the bottom and gas supplying system on the top; the processing steps include filling high-pressure pretreatment gas into reaction chamber-exhausting pretreatment gas-filling air-exhausting air and many other procedures; circulating above procedures until accomplishment of pretreatment on gas showerhead in the reaction chamber and other exposed components.

### CROSS-REFERENCE TO RELATED APPLICATIONS

The present application claims benefit of Chinese Application No. 201510747873.3, filed Nov. 6, 2015, the contents of which are incorporated herein by reference in their entirety.

### FIELD OF INVENTION

The present invention relates to the Metal Organic Chemical Vapor Deposition (MOCVD) manufacturing technical field, particularly to a method for pretreatment of gas showerhead in MOCVD.

### RELATED ART

As shown in FIG. 1, Metal Organic Chemical Vapor Deposition (MOCVD) reactor comprises a crystal growth reaction chamber 100; there is a tray 14 in the reaction chamber and many substrates to be processed are fixed on the tray; there is a rotation axis 10 under the center of tray 14 which rotates at high speed during the reaction process. There is a heater 12 under the tray 14 to heat the tray 14 to appropriate high temperature which is generally around 1000 degrees to accommodate the crystal growth of gallium nitride (GaN) crystalline material. A gas showerhead in the crystal growth reaction chamber 100 is opposite to the tray, including an upper cover 20 on the top, a gas distributor 22 in the middle and a cooling plate 24 at the bottom. The gas distributor 22 is connected to the gas source through reactive gas supply pipe 28. The gas distributor 22 includes multiple isolation plates to isolate different species of reactive gas in different gas diffusion chambers; the upper gas diffusion chamber includes many downward stretching gas conduits penetrating the lower gas diffusion chamber and reaching to corresponding vent hole or groove in cooling plate 24. The lower gas diffusion chamber may include many downward stretching gas conduits and the detailed layout may be optimized and designed according to different reaction chamber structure and crystal growth process, for example, the conduits flowing with TMG containing gallium and the conduits flowing with gas containing ammonia are alternately arranged. The cooling plate 24 contains coolant channels 226 uniformly distributed on the whole plane; there are vent holes or grooves among coolant channels which make the gases from the gas distributor 22 separately flow downward to reaction region and be mixed in reaction region. MOCVD reaction required high temperature up to 1000 degrees, so the entire reaction chamber and upper gas showerhead are mostly made of stainless steel to keep working in the high temperature circumstance. However, CP2Mg gas is introduced into MOCVD process and this gas is easy to react with stainless steel surface, so the iron on stainless steel surface will move to lower substrate together with the gas flow and significantly affect the LED illumination performance which produced by MOCVD process, it should be avoided strongly.

To prevent the occurrence of these reactions, the MOCVD reactor is pretreated before conducting MOCVD process in prior art. First, remove the tray 14 and extract the gas in reaction chamber so that the gas pressure in the reaction chamber approaches the vacuum; the heater 12 is used to apply sufficient power to heat the upper gas showerhead to the preset temperature; introduce plenty of CP2Mg gas and exhaust the gas through the lower evacuating device so that pretreatment gas forms gas flow in reaction chamber. The gas reacts with stainless steel surface of gas showerhead exposed in the gas flow, and the time period generally lasts for a few hours. In this process, partial CP2Mg reacts with iron on stainless steel surface to replace the iron atoms and leave the magnesium atoms on stainless steel surface. However, the magnesium could not solidly stay on the surface and further solidification is needed. Therefore, carry out next step: stop introducing CP2Mg and disconnect the heater power supply to cool down entire reaction chamber to lower temperature (such as lower than 100 degrees) to prevent heater metal damage due to oxidation; then introduce plenty of air into reaction chamber to up to atmospheric pressure. The oxygen and moisture in the air could react with magnesium on stainless steel surface to form stable chemical compound and prevent iron from being replaced into reactive gas. Repeat the step of introducing CP2Mg and air for many times until the iron on stainless steel surface is totally replaced and saturated.

The above method for stainless steel pretreatment has the serious problem, i.e., the processing cycle is too long. The reaction time with introduction of CP2Mg or air after reaching preset temperature is about a few hours, and entire pretreatment time generally exceeds one or more weeks after multiple cycles, heavily wasting equipment and materials. A new method is required to conduct pretreatment process for iron on stainless steel surface and also save processing time significantly.

### SUMMARY OF THE INVENTION

The objective of the present invention is pretreatment of gas showerhead of MOCVD reactor to reduce the pollution to wafer during the subsequent crystal growth stage. The present invention provides a method for MOCVD gas showerhead pretreatment, including: providing a reaction chamber, an evacuating system located at bottom of the reaction chamber to exhaust gas in the reaction chamber, and a gas showerhead to be treated fixed on top of the reaction chamber, wherein the gas showerhead includes a cooling plate at the bottom and a gas supplying system on the top; the cooling plate includes multiple cooling channels, and the gas supplying system is connected to a pretreatment gas source and an oxygen containing gas inlet; providing a heating device to heat the gas showerhead, so that the temperature of the gas showerhead is higher than 80 degrees; (A1) delivering pretreatment gas from the gas supplying system to the reaction chamber until gas pressure in the reaction chamber is higher than 400 torr, and maintaining the gas pressure for a first time period; (A2) exhausting the pretreatment gas in the reaction chamber by use of the evacuating system; (B1) delivering oxygen containing gas to the reaction chamber from the gas supplying system until the gas pressure in the reaction chamber reaches to an atmospheric pressure, and maintaining the atmospheric pressure for a second time period; (B2) exhausting the oxygen containing gas in the reaction chamber by use of the evacuating system; circularly executing steps A1 to B2 until completing the pretreatment on the gas showerhead.

The pretreatment gas include at least one of CP2Mg, TMG, TMAl, and the oxygen containing gas is air.

The reaction chamber is a MOCVD reaction chamber utilized to conduct MOCVD process, and the reaction chamber further comprises a substrate holding apparatus for holding substrates to be processed.

The evacuating system includes a extraction pipe and a vacuum pump, as well as a pressure regulating valve and a stop valve connected to the extraction pipe in series. The gas supplying system includes a first gas passage connected to pretreatment gas source, and a second gas passage connected to air inlet; the second gas passage is connected to an air flow limiter, a stop valve and an air filter in series.

In Step A1, shut down the extraction pipe stop valve. The first time period in Step A1 is less than 1 hour, and the preferred first time period is more than 10 minutes but less than 40 minutes. The gas pressure in reaction chamber in Step A1 is higher than 500 torr but lower than 600 torr.

The reaction chamber in present invention also includes a gas distribution plate located between gas showerhead and evacuating system; a buffer space connected to evacuating system is located between gas distribution plate and reaction chamber bottom.

The reaction chamber in present invention also includes a temperature sensor thermally coupled with the gas showerhead, which is used to detect the temperature of gas showerhead.

The heating device includes a heating fluid source connected to multiple cooling channels, so as to heat the cooling channels to be up to 80-250 degrees.

The present invention provides a method for MOCVD gas showerhead pretreatment comprising: providing a pretreatment chamber, an evacuating system connecting the pretreatment chamber to exhaust gas in the pretreatment chamber, and a gas showerhead to be treated fixed in the pretreatment chamber, wherein the gas showerhead includes a cooling plate and a gas supplying system; the cooling plate includes multiple cooling channels, and the gas supplying system is connected to a pretreatment gas source and an oxygen containing gas inlet; providing a heating device to heat the gas showerhead, so that the temperature of the gas showerhead is higher than 80 degrees; (A1) delivering pretreatment gas from the gas supplying system to the pretreatment chamber until gas pressure in the pretreatment chamber is higher than 400 torr, and maintaining the gas pressure for a first time period; (A2) exhausting the pretreatment gas in the pretreatment chamber by use of the evacuating system; (B1) delivering oxygen containing gas to the pretreatment chamber from the gas supplying system until the gas pressure in the pretreatment chamber reaches to an atmospheric pressure, and maintaining the atmospheric pressure for a second time period; (B2) exhausting the oxygen containing gas in the pretreatment chamber by use of the evacuating system; circularly executing steps A1 to B2 until completing the pretreatment on the gas showerhead.

wherein the pretreatment chamber further includes a gas distribution plate located between the gas showerhead and the evacuating system, and a buffer space connected to the evacuating system which is located between the gas distribution plate and the bottom of the pretreatment chamber. further the pretreatment gas include at least one of CP2Mg, TMG, TMAl, and the oxygen containing gas is air.

### BRIEF DESCRIPTION OF THE DRAWINGS

FIG. 1 is the schematic drawing of MOCVD reactor overall structure in the prior art;

FIG. 2 is the schematic drawing of pretreatment reaction chamber structure in the present invention;

FIG. 3 is the structure schematic drawing of second embodiment of pretreatment reaction chamber structure in the present invention;

FIG. 4 is the structure schematic drawing of third embodiment of pretreatment reaction chamber structure in the present invention.

### PREFERRED EMBODIMENTS OF THE INVENTION

The present invention is to solve the pollution on epitaxial growth wafer caused by iron in gas flow pipe in MOCVD reactor.

As shown in FIG. 2, the present invention proposes a pretreatment reactor for gas showerhead pretreatment, which comprises a pretreatment reaction chamber 200; there is a gas distribution plate 210 in pretreatment reaction chamber bottom which is used to distribute the flowing gas uniformly. There is a buffer space under gas distribution plate which is connected to a vacuum pump outside of pretreatment reaction chamber 200 through extraction pipe 212. A pressure regulating valve 214 and an extraction pipe stop valve 216 are connected between buffer space and vacuum pump in series to control the open or close of extraction pipe 212. The present invention can also achieve the objective without gas distribution plate 210. The upper part in pretreatment reaction chamber 200 includes the gas showerhead to be treated; the showerhead includes cooling plate 224; the cooling plate includes cooling channel 226, gas distributor 222 located above cooling plate, as well as showerhead upper cover 220 located above gas distributor 222. A gas pressure meter 230 can be equipped on side wall of pretreatment reaction chamber 200 to real-time monitor the gas pressure in pretreatment reaction chamber. In the present invention, one end of cooling channel 226 in cooling plate 224 is connected to a heating liquid source through coolant supply pipe 223, so that the high temperature fluid flows into cooling channel 226; meanwhile, cooling channel 226 also includes the other end looped to this heating fluid source through coolant supply pipe 225, so that high temperature heating fluid could flow in the cooling channel. The temperature in cooling plate could be controlled by controlling the temperature and flow rate of heating fluid output from heating fluid source. The gas distributor 222 in gas showerhead is connected to a reactive gas source through reactive gas supply pipe 228; meanwhile, the gas distributor 222 is also connected to atmosphere through air supply pipe 240; an air flow limiter 241, a stop valve 242 and an air filter 243 are connected into air supply pipe 240 in series. Reactive gas supply pipe 228 may include many mutually isolated gas supply pipes, and every gas supply pipe is connected to different reactive gas respectively, such as organometallic compound gases, ammonia, CP2Mg. The reactive gas supply pipes are connected to mutually isolated gas conduits in showerhead, and finally reactive gases are introduced to pretreatment reaction chamber through different nozzles of showerhead. Showerhead upper cover 220 also has a temperature sensor 202 to detect the temperature of showerhead. The sensor 202 may directly contact with showerhead to detect the temperature, or not contact with showerhead, by detecting temperature through radiating parameters of showerhead. As long as the sensor is thermally coupled with showerhead, it could obtain parameters relevant with showerhead's temperature, and the remote processor will calculate the corresponding temperature to meet the requirement of temperature detection.

The pretreatment comprises many processing steps, Step A: deliver heating fluid into cooling channel 226 in showerhead from heating fluid source to achieve higher temperature, such as 80-250 degrees with optimal temperature at 80-90 degrees. In the present invention, high temperature fluid may be directly introduced to make the gas showerhead have suitable target temperature, and pretreatment gas is introduced through reactive gas supply pipe 228. Pretreatment gas includes CP2Mg, trimethyl gallium (TMG), trimethylaluminum (TMAl) and other reactive gases or inert gases such as helium. Control the pressure regulating valve 214 so that gas pressure in pretreatment reaction chamber 200 reaches to suitable pretreatment gas pressure (gas pressure range: 400-600 torr); stop introducing gas in pretreatment reaction chamber so that pretreatment gas will be locked and diffuse in entire pretreatment reaction chamber, thus the introduced pretreatment gas will diffuses to the conduits without pretreatment gas introduced, so entire showerhead surface or even all internal walls of pretreatment reaction chamber could be pretreated. In the present invention, the pretreatment gas diffuses freely in pretreatment reaction chamber and does not form stable gas flow created by downstream vacuum pump and other extraction pipe. Therefore, it avoid the uneven pretreatment velocity distribution caused by uneven flow distribution, which ensures the treatment effect in relative short treatment time such as 10-40 minutes instead of a few hours used in the prior art. Step A can be finished within one hour until sufficient iron atoms on stainless steel surface are replaced. In the prior art, plenty of pretreatment gas is extracted downwards during the pretreatment gas introduction step, so gas pressure in pretreatment reaction chamber is relative low, only at 100-200 torr. The present invention could achieve relative high gas pressure because stop valve 216 of extraction pipe is closed.

Then enter into AB switching step: shut down the access from reactive gas supply pipe 228 to pretreatment reaction chamber 200 and open extraction pipe stop valve 216, enable vacuum pump to exhaust high pressure pretreatment gas in pretreatment reaction chamber until pretreatment reaction chamber reaches to vacuum state; close stop valve 216 to jump to Step B.

Step B includes: open air supply pipe stop valve 242 to introduce air into showerhead component and then flow into pretreatment reaction chamber 200. When the gas pressure in pretreatment reaction chamber achieves atmospheric pressure, maintain gas pressure for a certain time period, which could be 30-40 minutes or selected according to practical requirements.

BA switching step after Step B: close air supply pipe stop valve 242 and open extraction pipe stop valve 216 at the same time, so that the vacuum pump extracts air in pretreatment reaction chamber 200; when pretreatment reaction chamber almost reaches to vacuum, close stop valve 216 and jump to next pretreatment cycle. In step B, pretreatment chamber could also be filled with other oxygen containing mixed gas, any oxygen containing gas with enough oxygen concentration can perform a function similar to air.

Repeat above pretreatment cycle composed of Step A-AB switching step-Step B-BA switching step to achieve pretreatment on gas showerhead surface mentioned in the present invention.

In Step A of present invention, extracting pipe valve 216 could be under open state in addition to close state, but the valve opening of variable valve 214 should be simultaneously keeped at very low position, so that pretreatment gas extracted downwards can be significantly reduced and little introduced pretreatment gas could maintain high pressure in pretreatment reaction chamber, achieving the objective of the present invention, reducing entire pretreatment time of gas showerhead and save pretreatment gas.

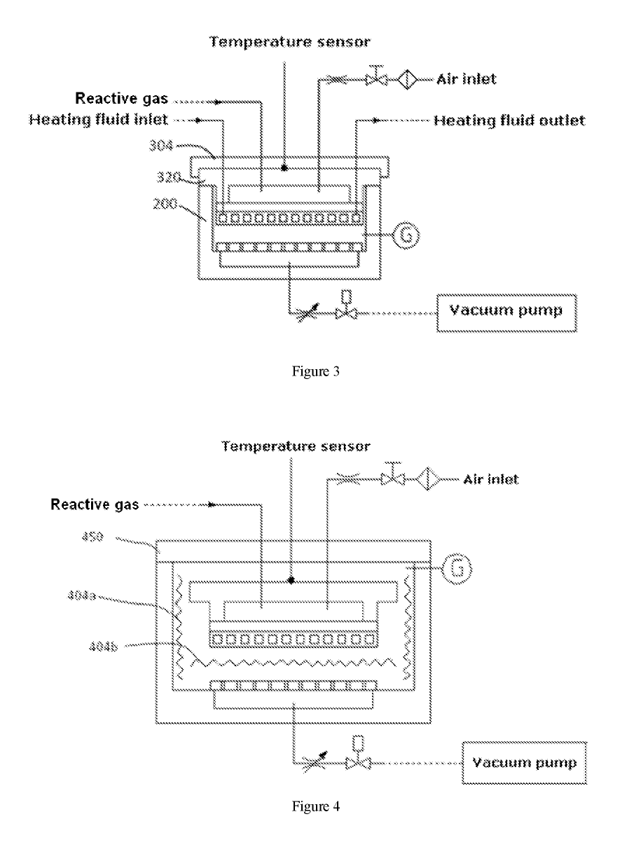

The pretreatment device in the present invention could be the structure of the second embodiment as shown in FIG. 3. The second embodiment is identical with other parts in the first embodiment. The main difference lies in that, a heater 304 is equipped above the gas showerhead upper cover 320, and the heater 304 could be heater band or heating jacket made of silicone rubber or insulation material Kapton, covering upper surface of showerhead upper cover 320. Heater 304 could also be a heating tube with insulation protective layer which is inserted into the hole on side wall of showerhead upper cover and removed after pretreatment process to avoid affecting subsequent crystal growth process. In the second embodiment, the gas showerhead can also be heated by the heater 304 on the top rather than heating fluid because the showerhead is made of stainless steel with high thermal conductance, thus ensuring that the bottom temperature of entire showerhead can be within target temperature 80-250 degrees when the top is heated to target temperature.

The pretreatment device in the present invention could be the structure of the third embodiment as shown in FIG. 4. The third embodiment is identical with other parts in the first and second embodiments, and the main difference lies in that, the gas showerhead is not heated through the heating fluid flowing into pipe in cooling plate; instead, multiple resistive heaters are set at inner wall of pretreatment device surrounding the gas showerhead to be treated, so that the gas showerhead reaches to target temperature, such as 80-250 degrees.

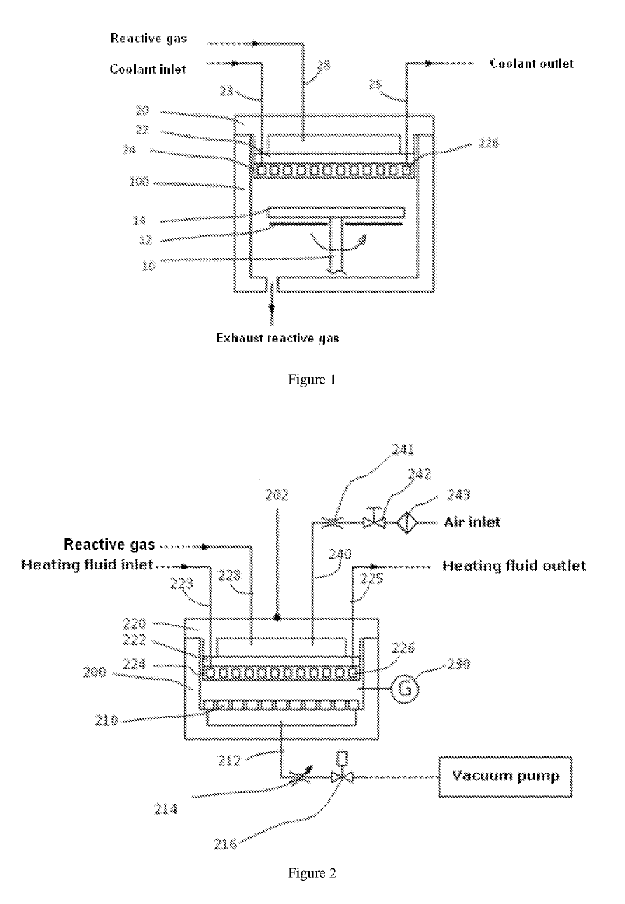

In addition to the dedicated pretreatment chamber as shown in FIG. 2-4, the present invention can also be applied in MOCVD reaction chamber as shown in FIG. 1. However, the MOCVD extraction port downstream shall include a stop valve. When the stop valve is closed, the pretreatment gas is introduced into pretreatment reaction chamber until the target gas pressure is achieved, then stop introduction of pretreatment gas and maintain high pressure in MOCVD reaction chamber. After the first time period, re-open the stop valve and extract pretreatment gas in pretreatment chamber to vacuum. The showerhead gas inlet in MOCVD reaction chamber also requires at least one process gas supply pipe which could be selectively connected to pretreatment gas source or air in different steps.

The present invention discloses a method special for MOCVD gas showerhead pretreatment, which by controlling the heater designed setted in the reactor or coolant supplied to showerhead, achieving widely adjust temperature control of the showerhead to be treated; the pretreatment gas is introduced after the temperature of showerhead in reactor reaches to target temperature; plenty of pretreatment gas is introduced into reaction chamber and stopped after gas pressure in reaction chamber reaches to high pressure; maintain high pressure state for a first time period and open stop valve to exhaust pretreatment gas in reaction chamber to achieve the vacuum. After the reaction chamber is vacuumed, the air is introduced into reaction chamber, maintaining for a second time period; then exhaust the air to vacuum pretreatment reaction chamber again; re-conduct the introduction of pretreatment gas steps; after several repeated cycles of introducing pretreatment gas-vacuuming-filling air-vacuuming, the stainless steel surface of gas showerhead exposed in reaction chamber is treated with good pretreatment performance, short pretreatment time and more uniform treatment effect.

The present invention is not limited to the above description. It should be understood that, persons of ordinary skill in the art can make lots of modifications and variations according to the concept of the present invention without creative efforts. Therefore, the protection scope of the present invention should fall within the scope as defined by the claims.

What is claimed is:

1. A method for MOCVD gas showerhead pretreatment comprising:
providing a reaction chamber, an evacuating system located at bottom of the reaction chamber to exhaust gas in the reaction chamber, and a gas showerhead to be treated fixed on top of the reaction chamber, wherein the gas showerhead includes a cooling plate at the bottom and a gas supplying system on the top; the cooling plate includes multiple cooling channels, and the gas supplying system is connected to a pretreatment gas source and an oxygen containing gas inlet;
providing a heating device to heat the gas showerhead, so that the temperature of the gas showerhead is higher than 80 degrees;
(A1) delivering pretreatment gas from the gas supplying system to the reaction chamber until gas pressure in the reaction chamber is higher than 400 torr, and maintaining the gas pressure for a first time period;
(A2) exhausting the pretreatment gas in the reaction chamber by use of the evacuating system;
(B1) delivering oxygen containing gas to the reaction chamber from the gas supplying system until the gas pressure in the reaction chamber reaches to an atmospheric pressure, and maintaining the atmospheric pressure for a second time period;
(B2) exhausting the oxygen containing gas in the reaction chamber by use of the evacuating system;
circularly executing steps A1 to B2 until completing the pretreatment on the gas showerhead.

2. The method for MOCVD gas showerhead pretreatment of claim 1, wherein the reaction chamber further includes a temperature sensor thermally coupled with the gas showerhead to detect the temperature of the gas showerhead.

3. The method for MOCVD gas showerhead pretreatment of claim 1, wherein the heating device includes a heating fluid source connected to the multiple cooling channels, so as to heat the cooling channels to be up to 80-250 degrees.

4. The method for MOCVD gas showerhead pretreatment of claim 1, wherein the reaction chamber further includes a gas distribution plate located between the gas showerhead and the evacuating system, and a buffer space connected to the evacuating system which is located between the gas distribution plate and the bottom of the reaction chamber.

5. The method for MOCVD gas showerhead pretreatment of claim 1, wherein the evacuating system includes an extraction pipe and a vacuum pump, as well as a pressure regulating valve and a stop valve connected to the extraction pipe in series.

6. The method for MOCVD gas showerhead pretreatment of claim 1, wherein the gas supplying system includes a first gas passage connected to the pretreatment gas source and a second gas passage connected to an air inlet, wherein the second gas passage is connected to an air flow limiter, a stop valve and an air filter in series.

7. The method for MOCVD gas showerhead pretreatment of claim 5, wherein step A1 further comprises shutting down the stop valve.

8. The method for MOCVD gas showerhead pretreatment of claim 1, wherein the first time period in step A1 is less than 1 hour.

9. The method for MOCVD gas showerhead pretreatment of claim 1, wherein the first time period is more than 10 minutes but less than 40 minutes.

10. The method for MOCVD gas showerhead pretreatment of claim 1, wherein the gas pressure in the reaction chamber in step A1 is higher than 500 torr but lower than 600 torr.

11. The method for MOCVD gas showerhead pretreatment of claim 1, wherein the pretreatment gas include at least one of CP2Mg, TMG, TMAl, and the oxygen containing gas is air.

12. The method for MOCVD gas showerhead pretreatment of claim 1, wherein the reaction chamber is a MOCVD reaction chamber utilized to conduct MOCVD process, and the reaction chamber further comprises a substrate holding apparatus for holding substrates to be processed.

13. A method for MOCVD gas showerhead pretreatment comprising:
providing a pretreatment chamber, an evacuating system connecting the pretreatment chamber to exhaust gas in the pretreatment chamber, and a gas showerhead to be treated fixed in the pretreatment chamber, wherein the gas showerhead includes a cooling plate and a gas supplying system; the cooling plate includes multiple cooling channels, and the gas supplying system is connected to a pretreatment gas source and an oxygen containing gas inlet;
providing a heating device to heat the gas showerhead, so that the temperature of the gas showerhead is higher than 80 degrees;
(A1) delivering pretreatment gas from the gas supplying system to the pretreatment chamber until gas pressure in the pretreatment chamber is higher than 400 torr, and maintaining the gas pressure for a first time period;
(A2) exhausting the pretreatment gas in the pretreatment chamber by use of the evacuating system;
(B1) delivering oxygen containing gas to the pretreatment chamber from the gas supplying system until the gas pressure in the pretreatment chamber reaches to an atmospheric pressure, and maintaining the atmospheric pressure for a second time period;
(B2) exhausting the oxygen containing gas in the pretreatment chamber by use of the evacuating system;
circularly executing steps A1 to B2 until completing the pretreatment on the gas showerhead.

14. The method for MOCVD gas showerhead pretreatment of claim 13, wherein the pretreatment chamber further includes a gas distribution plate located between the gas showerhead and the evacuating system, and a buffer space connected to the evacuating system which is located between the gas distribution plate and the bottom of the pretreatment chamber.

15. The method for MOCVD gas showerhead pretreatment of claim 1, wherein the pretreatment gas include at least one of CP2Mg, TMG, TMAl, and the oxygen containing gas is air.
